(19) United States
(12) Patent Application Publication
(10) Pub. No.: US 2014/0287170 A1
(43) Pub. Date: Sep. 25, 2014

(54) REFLECTIVE LINERS

(71) Applicant: Applied Materials, Inc., Santa Clara, CA (US)

(72) Inventors: JOSEPH M. RANISH, San Jose, CA (US); Paul Brillhart, Pleasanton, CA (US); Surajit Kumar, Sunnyvale, CA (US)

(21) Appl. No.: 14/186,566

(22) Filed: Feb. 21, 2014

Related U.S. Application Data
(60) Provisional application No. 61/806,490, filed on Mar. 29, 2013.
(60) Provisional application No. 61/804,512, filed on Mar. 22, 2013.

(51) Int. Cl. H01L 21/67

(52) U.S. Cl. CPC H01L 21/67098
USPC 428/34.1

(57) ABSTRACT

An apparatus for processing a semiconductor substrate is described. The apparatus is a process chamber having an optically transparent upper dome and lower dome. Vacuum is maintained in the process chamber during processing. The upper dome is thermally controlled by flowing a thermal control fluid along the upper dome outside the processing region. Thermal lamps are positioned proximate the lower dome, and thermal sensors are disposed among the lamps. The lamps are powered in zones, and a controller adjusts power to the lamp zones based on data received from the thermal sensors. A reflective liner may provide for improved temperature measurement and heating of a substrate.

### CROSS-REFERENCE TO RELATED APPLICATIONS

This application claims benefit of U.S. provisional patent application No. 61/806,490, filed Mar. 29, 2013, and U.S. provisional patent application No. 61/804,512, filed Mar. 22, 2013, both of which are hereby incorporated by reference.

### FIELD

An apparatus for semiconductor processing are disclosed herein. More specifically, embodiments disclosed herein relate to a reflective liner for use in a semiconductor processing chamber.

### BACKGROUND

Epitaxy is a process that is used extensively in semiconductor processing to form very thin material layers on semiconductor substrates. These layers frequently define some of the smallest features of a semiconductor device, and they may have a high quality crystal structure if the electrical properties of crystalline materials are desired. A deposition precursor is normally provided to a processing chamber in which a substrate is disposed, the substrate is heated to a temperature that favors growth of a material layer having desired properties.

It is usually desired that the film have very uniform thickness, composition, and structure. Because of variations in local substrate temperature, gas flows, and precursor concentrations, it is quite challenging to form films having uniform and repeatable properties. The processing chamber is normally a vessel capable of maintaining high vacuum, typically below 10 Torr, and heat is normally provided by heat lamps positioned outside the vessel to avoid introducing contaminants. Pyrometers may be provided to measure the temperature of the substrate. Control and measurement of substrate temperature, and therefore of local layer formation conditions, is complicated by thermal absorptions and emissions of chamber components and exposure of sensors and chamber surfaces to film forming conditions inside the processing chamber. There remains a need for an epitaxy chamber with improved temperature control, temperature measurement, and methods of operating such a chamber to improve uniformity and repeatability.

### SUMMARY

Embodiments disclosed herein relate to reflective liners for use in a semiconductor processing chamber. The reflective liners may improve temperature control and measurement of a substrate in a processing chamber.

Embodiments described herein provide an apparatus for use in a semiconductor processing chamber. The apparatus comprises a right circular cylindrical annulus shaped reflective liner having an outer part, an inner part, and a volume between the outer part and the inner part. A reflective member is moveably disposed in the volume.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of a process chamber according to one embodiment described herein.

### DETAILED DESCRIPTION

A chamber capable of zoned temperature control of a substrate while performing an epitaxy process has a processing vessel with an upper portion, a side portion, and a lower portion all made of a material having the capability to maintain its shape when high vacuum is established within the vessel. At least the lower portion is substantially transparent to thermal radiation, and thermal lamps may be positioned in a conical lamphead structure coupled to the lower portion of the processing vessel on the outside thereof. Thermal sensors are disposed at various locations inside the processing vessel with means for reducing thermal noise into the sensors and material deposition on the sensors.

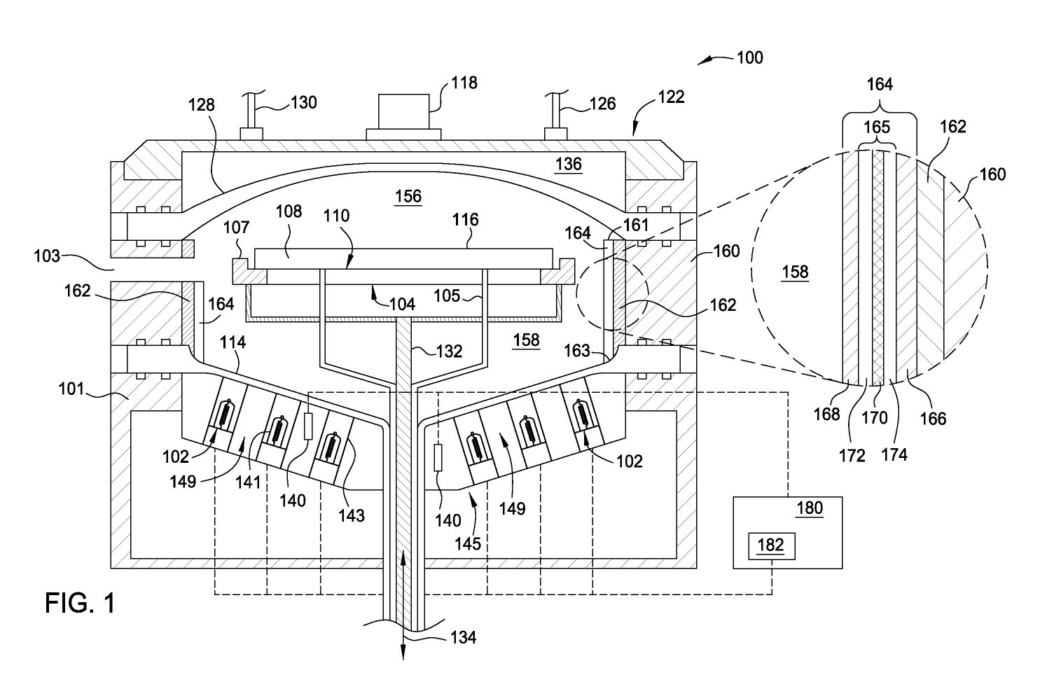

FIG. 1 is a schematic cross-sectional view of a process chamber 100 according to one embodiment. The process chamber 100 may be used to process one or more substrates, including the deposition of a material on an upper surface of a substrate 108. The process chamber 100 generally includes a chamber body 101 and an array of radiant heating lamps 102 for heating, among other components, a backside 104 of a substrate support 107 disposed within the process chamber 100. The substrate support 107 may be a ring-like substrate support as shown, which supports the substrate 108 from the edge of the substrate 108, a disk-like or platter-like substrate support, or a plurality of pins, for example, three pins or five pins. The substrate support 107 is located within the process chamber 100 between an upper dome 128 and a lower dome 114. The substrate 108 may be brought into the process chamber 100 and positioned onto the substrate support 107 through a loading port 103.

The substrate support 107 is shown in an elevated processing position, but may be vertically traversed by an actuator (not shown) to a loading position below the processing position to allow lift pins 105 to contact the lower dome 114. The lift pins 105 pass through holes in the substrate support 107 and raise the substrate 108 from the substrate support 107. A robot (not shown) may then enter the process chamber 100 to engage and remove the substrate 108 therefrom though the loading port 103. The substrate support 107 then may be actuated up to the processing position to place the substrate 108, with its device side 116 facing up, on a front side 110 of the substrate support 107.

The substrate support 107, while located in the processing position, divides the internal volume of the process chamber 100 into a process gas region 156 (above the substrate) and a purge gas region 158 (below the substrate support 107). The substrate support 107 is rotated during processing by a central shaft 132 to minimize the effect of thermal and process gas flow spatial non-uniformities within the process chamber 100 and thus facilitate uniform processing of the substrate 108. The substrate support 107 is supported by the central shaft 132, which moves the substrate 108 in an up and down direction 134 during loading and unloading, and in some instances, during processing of the substrate 108. The substrate support 107 is typically formed from a material having low thermal mass or low heat capacity, so that energy absorbed and emitted by the substrate support 107 is minimized. The substrate support 107 may be formed from silicon carbide or graphite coated with silicon carbide to absorb radiant energy from the lamps 102 and conduct the radiant energy to the substrate 108. The substrate support 107 is shown in FIG. 1 as a ring with a central opening to facilitate exposure of the substrate to the thermal radiation from the lamps 102. The substrate support 107 may also be a platter-like member with no central opening.

In general, the upper dome 128 and the lower dome 114 are typically formed from an optically transparent material such as quartz. The upper dome 128 and the lower dome 114 are thin to minimize thermal memory, typically having a thickness between about 3 mm and about 10 mm, for example about 4 mm. The upper dome 128 may be thermally controlled by introducing a thermal control fluid, such as a cooling gas, through an inlet portal 126 into a thermal control space 136, and withdrawing the thermal control fluid through an exit portal 130. In some embodiments, a cooling fluid circulating through the thermal control space 136 may reduce deposition on an inner surface of the upper dome 128.

One or more lamps, such as an array of lamps 102, can be disposed adjacent to and beneath the lower dome 114 in a desired manner around the central shaft 132 to heat the substrate 108 as the process gas passes over the substrate 108, thereby facilitating the deposition of a material onto the upper surface of the substrate 108. In various examples, the material deposited onto the substrate 108 may be a group III, group IV, and/or group V material, or may be a material including a group III, group IV, and/or group V dopant. For example, the deposited material may include gallium arsenide, gallium nitride, or aluminum gallium nitride.

The lamps 102 may be adapted to heat the substrate 108 to a temperature within a range of about 200 degrees Celsius to about 1200 degrees Celsius, such as about 300 degrees Celsius to about 950 degrees Celsius. The lamps 102 may include bulbs 141 surrounded by an optional reflector 143. Each lamp 102 is coupled to a power distribution board (not shown) through which power is supplied to each lamp 102. The lamps 102 are positioned within a lamphead 145 which may be cooled during or after processing by, for example, a cooling fluid introduced into channels 149 located between the lamps 102. The lamphead 145 conductively cools the lower dome 114 due in part to the close proximity of the lamphead 145 to the lower dome 114. The lamphead 145 may also cool the lamp walls and walls of the reflectors 143. If desired, the lampheads 145 may be in contact with the lower dome 114.

A liner assembly 162 may be disposed within or surrounded by an inner circumference of a base ring 160. The base ring 160 may form a portion of the chamber body 101. The liner assembly 162 may be formed from a quartz material and generally shields the processing volume (i.e., the process gas region 156 and purge gas region 158) from metallic walls of the process chamber 100. The metallic walls may react with precursors and cause contamination in the processing volume. An opening may be disposed through the liner assembly 162 and aligned with the loading port 103 to allow for passage of the substrate 108. While the liner assembly 162 is shown as a single piece, it is contemplated that the liner assembly 162 may be formed from multiple pieces.

A reflective liner 164 may be disposed within or surrounded by an inner circumference of the liner assembly 162. The reflective liner 164 may be shaped as a right circular cylindrical annulus having a cutout portion adapted to allow for substrate transport through the reflective liner 164. In the embodiment shown, the reflective liner 164 does not provide a portion above the loading port 103, however, it is contemplated that the liner may comprise a portion disposed above the loading port 103. In the embodiment shown, the reflective liner 164 may be supported by a portion of the lower dome 114. In another embodiment, the reflective liner 164 may be supported by a portion (not shown) of the liner assembly 162 that extends radially inward from an inner radius of the liner assembly 162. The portion, or ledge, may be discontinuous comprising a plurality of segments. The reflective liner 164 may comprise an outer part 166, an inner part 168, and a reflective member 170. The outer part 166 and inner part 168 may be made from an optically transparent material, such as quartz. The outer part 166 may be disposed adjacent to the inner circumference of the liner assembly 162. The inner part 168 may be disposed adjacent the process gas region 156 and the purge gas region 158. In certain embodiments, the outer part 166 and the inner part 168 may be coupled together to form a volume 165. In this embodiment, the coupling may be performed by a quartz weld at a top region 161 and a bottom region 163 and the volume 165 may be provided under vacuum. In certain embodiments, a pressure in the volume 165 may be between about 1 μTorr to about 10 Torr.

In certain embodiments, the reflective member 170 may be disposed in the volume 165 between the outer part 166 and the inner part 168. The volume 165 between the outer part 166 and inner part 168 where the reflective member 170 may be disposed generally has a thickness greater than a thickness of the reflective member 170. In certain embodiments, the thickness of the reflective member may be between about 4 mils and about 40 mils. As a result, a first gap 172 may be provided between the inner part 168 and the reflective member and a second gap 174 may be provided between the outer part 166 and the reflective member 170. Accordingly, the reflective member 170 may be “free floating,” or moveably disposed between the outer part 166 and the inner part 168. In another embodiment, the reflective member 170 may be encased between the outer part 166 and the inner part 168 such that the reflective member 170 may be in physical contact with both the outer part 166 and the inner part 168. In another embodiment, the reflective member 170 may be disposed adjacent to and in contact with the outer part 166. In this embodiment, a plurality of positioning members (not shown), such as pillars or protrusions, may extend from the inner part 168 and contact the reflective member 170 such that the positioning members urge the reflective member 170 against the outer part 166. In this embodiment, a getter (not shown) may also be disposed between the outer part 166 and the inner part 168 to maintain a vacuum. The getter may comprise a zirconium compound or other suitable getter material to adsorb a gas, such as hydrogen, which may leak into the volume 165 from the processing gas region 156.

In certain embodiments, the reflective member 170 may comprise a plurality of sections (not shown). In this embodiment, the plurality of sections may be positioned to overlap where the sections are adjacent one another. In another embodiment, the plurality of sections may not overlap but may be positioned in a manner such that substantially no radiation may penetrate a gap between the plurality of portions when the reflective member is exposed to radiation. In either embodiment, the spacing and location of the reflective member 170 may account for expansion of the reflective member 170 during exposure to radiation. More specifically, the positioning of the reflective member 170 may be selected to accommodate for physical movement of the reflective member 170 under thermal stress.

The reflective member 170 may be a specular reflector such that light provided to the reflective member 170 has angle of incidence which equals the angle of reflection. The reflective member 170 may be a broadband reflector such as a metallic reflector or a dielectric film stack, or a combination thereof. In certain embodiments, the reflective member 170 may be coated by or encase in a transparent barrier material, such as silica. In one example, the reflective member 170 may be formed from a dielectric stack comprising silica (SiO₂), titania (TiO₂), tantalum oxide (Ta₂O₅), or combinations thereof. In another example, the reflective member 170 may be formed from a metal suited to withstand temperatures in the processing chamber 100, such as aluminum, gold, silver, platinum, tungsten, tantalum, or combinations thereof.

In certain embodiments, surfaces defining the volume 165 may be coated with a reflective material. For example, every surface defining the volume 165, such as surfaces facing the volume 165 of the outer part 166 and the inner part 168 and a bottom surface (not shown) defining the volume 165 may be coated with a reflective material. In one embodiment, the surfaces defining the volume 165 may be coated with a reflective material by electroless plating, such as electroless nickel or electroless silver plating. In this embodiment, the volume 165 may be filled with an aqueous plating solution and the eletroless plating process may proceed to plate the surfaces defining the volume 165 with nickel or silver. It has been contemplated that other reflective materials, such as gold and copper, may also be disposed on the surfaces defining the volume 165 by electroless plating. After the electroless plating of the surfaces defining the volume 165 has been performed, the aqueous solution may be evacuated from the volume 165 and a top surface (not shown) may be formed to join the outer part 166 and the inner part 168. The top surface may be formed by a quartz weld. In this embodiment, the volume 165 may be provided under vacuum similar to previously described embodiments. The surfaces defining the volume 165 coated with the reflective material may act as a specular reflector.

As a result of backside heating of the substrate 108 from the substrate support 107 in combination with the reflective liner 164, the use of an optical pyrometer 118 for temperature measurements/control on the substrate support can be performed. The reflective liner 164 reduces or eliminates undesirable effects of stray radiation on measurement of the substrate 108 temperature using the optical pyrometer 118. The reflective liner 164 may also direct radiation toward an outer part of the substrate 108 to improve control of a radial temperature profile of the substrate 108. Further, the reflective liner 164 reduces radiative heating of the liner assembly 162 by reflecting radiation away from the liner assembly 164 and toward the outer part of the substrate 108.

The optical pyrometer 118 may be disposed at a region above the upper dome 128. This temperature measurement by the optical pyrometer 118 may also be done on substrate device side 116 having an unknown emissivity since heating the substrate support front side 110 in this manner is emissivity independent. As a result, the optical pyrometer 118 can only sense radiation from the hot substrate 108 that conducts from the substrate support 107 or radiates from the lamps 102, with minimal background radiation from the lamps 102 directly reaching the optical pyrometer 118. In certain embodiments, multiple pyrometers may be used and may be disposed at various locations above the upper dome 128.

A reflector 122 may be optionally placed outside the upper dome 128 to reflect infrared light that is radiating from the substrate 108 or transmitted by the substrate 108 back onto the substrate 108. Due to the reflected infrared light, the efficiency of the heating will be improved by containing heat that could otherwise escape the process chamber 100. The reflector 122 can be made of a metal such as aluminum or stainless steel. The reflector 122 can have machined channels (not shown) to carry a flow of a fluid such as water for cooling the reflector 122. If desired, the efficiency of the reflection can be improved by coating a reflector area with a highly reflective coating, such as a gold coating.

A plurality of thermal radiation sensors 140, which may be pyrometers or light pipes, such as sapphire light pipes, may be disposed in the lamphead 145 for measuring thermal emissions of the substrate 108. The sensors 140 are typically disposed at different locations in the lamphead 145 to facilitate viewing different locations of the substrate 108 during processing. In embodiments using light pipes, the sensors 140 may be disposed on a portion of the chamber body 101 below the lamphead 145. Sensing thermal radiation from different locations of the substrate 108 facilitates comparing the thermal energy content, for example the temperature, at different locations of the substrate 108 to determine whether temperature anomalies or non-uniformities are present. Such non-uniformities can result in non-uniformities in film formation, such as thickness and composition. At least two sensors 140 are used, but more than two may be used. Different embodiments may use three, four, five, six, seven, or more sensors 140.

Each sensor 140 views a zone of the substrate 108 and senses the thermal state of a zone of the substrate. The zones may be oriented radially in some embodiments. For example, in embodiments where the substrate 108 is rotated, the sensors 140 may view, or define, a central zone in a central portion of the substrate 108 having a center substantially the same as the center of the substrate 108, with one or more zones surrounding the central zone and concentric therewith. It is not required that the zones be concentric and radially oriented, however. In some embodiments, zones may be arranged at different locations of the substrate 108 in non-radial fashion.

The sensors 140 are typically disposed between the lamps 102, for example in the channels 149, and are usually oriented substantially normal to the substrate 108. In some embodiments the sensors 140 are oriented normal to the substrate 108, while in other embodiments, the sensors 140 may be oriented in slight departure from normality. An orientation angle within about 5° of normal is most frequently used.

The sensors 140 may be attuned to the same wavelength or spectrum, or to different wavelengths or spectra. For example, substrates used in the chamber 100 may be compositionally homogeneous, or they may have domains of different compositions. Using sensors 140 attuned to different wavelengths may allow monitoring of substrate domains having different composition and different emission responses to thermal energy. Typically, the sensors 140 are attuned to infrared wavelengths, for example about 4 μm.

A controller 180 receives data from the sensors 140 and separately adjusts power delivered to each lamp 102, or individual groups of lamps or lamp zones, based on the data. The controller 180 may include a power supply 182 that independently powers the various lamps or lamp zones. The controller 180 can be configured with a desired temperature profile, and based on comparing the data received from the sensors 140, the controller 180 adjusts power to lamps and/or lamp zones to conform the observed thermal data to the desired temperature profile. The controller 180 may also adjust power to the lamps and/or lamp zones to conform the thermal treatment of one substrate to the thermal treatment of another substrate, in the event chamber performance drifts over time.

While the foregoing is directed to embodiments of the present invention, other and further embodiments of the invention may be devised without departing from the basic scope thereof, and the scope thereof is determined by the claims that follow.

1. An apparatus for use in a semiconductor processing chamber, comprising:
a right circular cylindrical annulus shaped reflective liner, comprising:
an outer part, an inner part, and a volume between the outer part and the inner part; and
a reflective member moveably disposed in the volume.

2. The apparatus of claim 1, wherein each of the outer part and inner part comprises an optically transparent material.

3. The apparatus of claim 2, wherein the transparent material is quartz.

4. The apparatus of claim 1, wherein the volume is maintained at a pressure between about 1 μTorr and about 10 Torr.

5. The apparatus of claim 1, wherein the reflective member is moveably disposed within the volume.

6. The apparatus of claim 1, further comprising a first gap between the inner part and the reflective member.

7. The apparatus of claim 6, further comprising a second gap between the outer part and the reflective member.

8. The apparatus of claim 1, wherein the reflective member comprising silica, titania, tantalum oxide, or combinations thereof.

9. The apparatus of claim 1, wherein the reflective member comprising aluminum, gold, silver, platinum, tungsten, tantalum, or combinations thereof.

10. The apparatus of claim 1, wherein the reflective liner is a specular reflector.

11. The apparatus of claim 1, wherein a thickness of the reflective liner is between about 4 mils and about 40 mils.

12. The apparatus of claim 1, wherein a reflective material may be disposed on surfaces defining the volume.

13. The apparatus of claim 12, wherein the reflective material may be formed by an electroless plating process.

14. The apparatus of claim 13, wherein the reflective material may be a nickel material or a silver material.
